(19) United States
(12) Patent Application Publication
(10) Pub. No.: US 2009/0252346 A1
(43) Pub. Date: Oct. 8, 2009

(54) METHOD OF PROCESSING AUDIO FILES

(76) Inventor: Hsin-Yuan Kuo, Kaohsiung County (TW)

Correspondence Address: WPAT, PC;INTELLECTUAL PROPERTY ATTORNEYS, 2030 MAIN STREET, SUITE 1300, IRVINE, CA, 92614, US

(21) Appl. No.: 12/062,381

(22) Filed: Apr. 3, 2008

(51) Int. Cl. H03G 5/00

(52) U.S. Cl. 381/98

(57) ABSTRACT

A method of processing audio files includes the steps of providing an audio frequency adjusting section, via which one or more first audio files may be changed in the frequency property thereof to create one or more second audio files without the need of opening the first audio files. In this manner, a plurality of audio files may be easily and quickly modified at one time via the audio frequency adjusting section to shorten the time needed to optimize the tone quality of the audio files.

### FIELD OF THE INVENTION

The present invention relates to a method of processing audio files, and more particularly to a method for changing the frequency property of one or more first audio files to create one or more second audio files without the need of opening the first audio files.

### BACKGROUND OF THE INVENTION

Generally, a digital music format, such as MP3, is a compressed CD audio file to reduce the transmission bandwidth thereof. Compared to the sound track of the original CD audio file, the compressed CD audio file has degraded tone quality due to the compressed and weakened tone details and extended frequency signals in the MP3 format. Besides, when a user listens to music via a computer or low-price stereos, due to interferences in circuit operation or adverse influences by the low-grade stereos, the music played back often has a poor quality. Also, the audio file in MP3 format is often reproduced for broadcasting or backup. In the reproduction procedure, there is a further loss of the tone quality of the audio file. Consequently, due to the above external and internal factors, the playback effect of the music is descended. Therefore, in the digital video/audio field, it has become a major issue to improve the tone quality of audio files.

A current solution to the degraded tone quality, particularly to the treble and bass frequency, is to compensate or modulate the audio signal frequency when playing back the music, just as the solution in the era of analog music. This can be achieved via an equalizer or the like. While the above measure may somewhat improve the tone quality, it necessitates playback apparatus or playback software having such modulation function. However, not all the available playback apparatuses or playback software has such function. Even if some of the available playback apparatuses or playback software has such function, they provide different and only limited effects in improving the tone quality.

To overcome the above-mentioned problems, some manufacturers have tried to directly add a tone quality-enhancing effect to the audio file. That is, to change the audio file itself. Accordingly, when playing back music, the tone quality of the audio file can be improved without the need of additional processing function. However, professional music composition software is often needed for changing the tone quality of the audio file itself. Although many application programs and software for processing multimedia files are currently available, it is inconvenient to use these application programs and software. For example, the music composition software provides various functions for processing audio files, and the operating menus of related audio processing software involve in many nomenclatures and acoustic knowledge that is uneasy for a general users to understand. Only those users with professional acoustic knowledge are able to deal with such operating menus. Moreover, to provide powerful functions, the audio processing software includes so many complicated details that only one audio file can be processed at a time. And, as a matter of fact, since most general audio file users would use only a few functions of the audio processing software, it is inconvenient and unpractical for general users to use such highly complicated and professional audio processing software to process multimedia files or audio/visual files.

### SUMMARY OF THE INVENTION

It is therefore a primary object of the present invention to provide a method of processing audio files that allows a user to easily and quickly modify a plurality of audio files at one time via an audio frequency adjusting section.

To achieve the above and other objects, the method of processing audio files according to the present invention includes the basic steps of: (1) providing an audio frequency adjusting section; and (2) changing the frequency property of one or more first audio files via the audio frequency adjusting section to create one or more second audio files without the need of opening the first audio files.

In the method of the present invention, the audio frequency adjusting section is driven via audio frequency adjusting software.

In the method of the present invention, the audio frequency adjusting section is a treble boost section, a mid boost section, or a bass boost section. The treble boost section enhances an intensity of signals of the first audio files having a frequency of 2000 Hz via treble boost software; the mid boost section enhances an intensity of signals of the first audio files having a frequency of 1000 Hz via mid boost software; and, the bass boost section enhances an intensity of signals of the first audio files having a frequency of 100 Hz via bass boost software.

In the method of the present invention, the first audio files and the audio frequency adjusting section are provided on a file-processing platform. The audio frequency adjusting section includes a plurality of audio frequency adjusting modules in one-to-one correspondence to the first audio files. Each of the audio frequency adjusting modules includes at least one audio frequency adjusting unit, which is driven via audio frequency adjusting software. The audio frequency adjusting unit may be a treble boost unit, a mid boost unit, or a bass boost unit. The treble boost unit enhances an intensity of signals of the first audio files having a frequency of 2000 Hz via treble boost software. The mid boost unit enhances an intensity of signals of the first audio files having a frequency of 1000 Hz via mid boost software. The bass boost unit enhances an intensity of signals of the first audio files having a frequency of 100 Hz via bass boost software. And, the first audio files are corresponding to a trial listening unit and a stop unit each.

In the method of the present invention, the first audio files and the audio frequency adjusting section are provided on a file-processing platform, and the audio frequency adjusting section is driven via audio frequency adjusting software. The audio frequency adjusting section may be a treble boost section, a mid boost section, or a bass boost section. The treble boost section enhances an intensity of signals of the first audio files having a frequency of 2000 Hz via treble boost software; the mid boost section enhances an intensity of signals of the first audio files having a frequency of 1000 Hz via mid boost software; and the bass boost section enhances an intensity of signals of the first audio files having a frequency of 100 Hz via a bass boost software. And, the first audio files are corresponding to a trial listening unit and a stop unit each.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flowchart showing the basic steps included in the method of processing audio files according to the present invention;

FIG. 2 shows detailed steps in the method of processing audio files according to a first preferred embodiment of the present invention;

FIG. 3 shows detailed steps in the method of processing audio files according to a second preferred embodiment of the present invention;

FIG. 4 shows the method of processing audio files according to a third preferred embodiment of the present invention;

FIG. 5 shows the method of processing audio files according to a fourth preferred embodiment of the present invention; and

FIG. 6 shows the method of processing audio files according to a fifth preferred embodiment of the present invention.

### DETAILED DESCRIPTION OF THE PREFERRED EMBODIMENTS

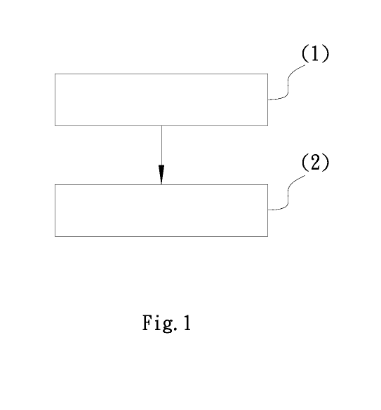

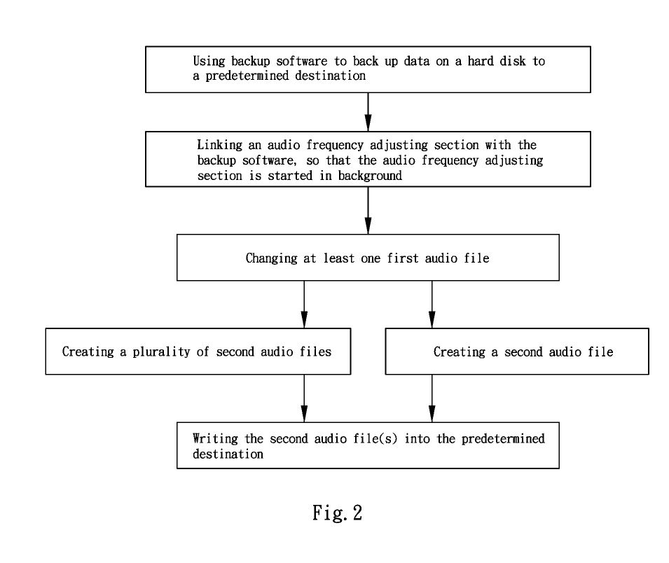

Please refer to FIG. 1 that is a flowchart showing the basic steps included in a method of processing audio files according to the present invention, and to FIG. 2 that shows more detailed steps for processing audio files in the method according to a first preferred embodiment of the present invention. As shown, the method of the present invention includes the following basic steps:

Step 1: providing an audio frequency adjusting section; and

Step 2: changing the frequency property of one or more first audio files via the audio frequency adjusting section to create one or more second audio files without the need of opening the first audio files.

The audio frequency adjusting section is driven via audio frequency adjusting software. When a user uses backup software to back up data on the hard disk to a predetermined destination, the audio frequency adjusting section is linked with the backup software and started in background on the computer. At this point, the user may change the frequency property of the first audio files via the audio frequency adjusting section to create one or more second audio files without the need of opening the first audio files on desktop.

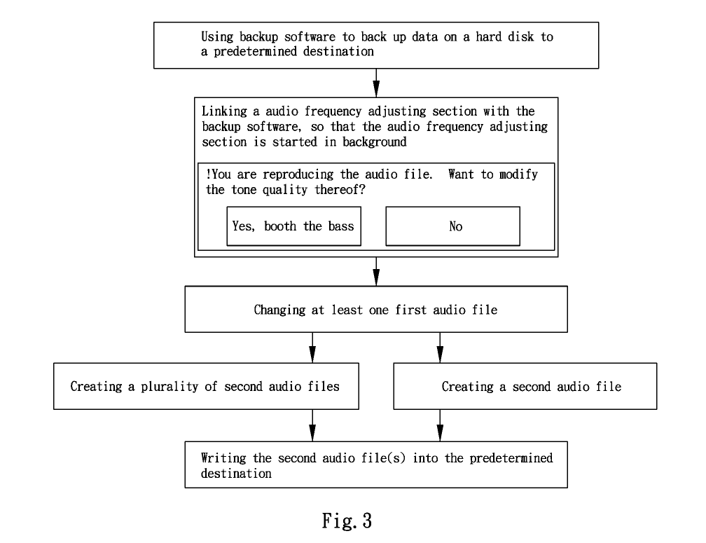

FIG. 3 shows detailed steps for processing audio files in the method according to a second preferred embodiment of the present invention. As shown, the audio frequency adjusting section can be a treble boost section, a mid boost section, or a bass boost section. Via treble boost software, the treble boost section enhances the intensity of the signals of the first audio files having a frequency of 2000 Hz. Via mid boost software, the mid boost section enhances the intensity of the signals of the first audio files having a frequency of 1000 Hz. Via bass boost software, the bass boost section enhances the intensity of the signals of the first audio files having a frequency of 100 Hz. When using backup software to back up data on the hard disk to a predetermined destination, the audio frequency adjusting section is linked with the backup software and started in background. At this point, the user may change the frequency property of the first audio files via the audio frequency adjusting section to create one or more second audio files without the need of opening the first audio files on desktop.

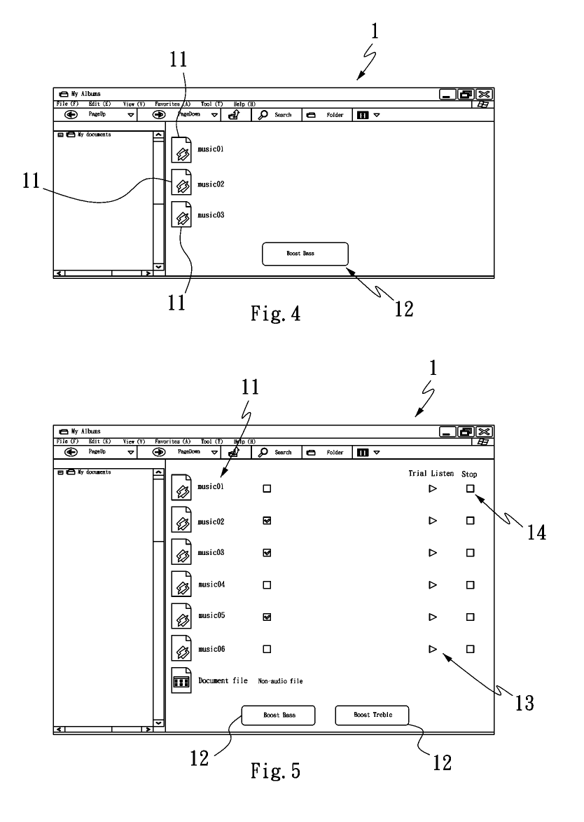

FIG. 4 shows the method of processing audio files according to a third preferred embodiment of the present invention. As shown, the first audio files 11 and the audio frequency adjusting section 12 may be provided on a file-processing platform 1. The audio frequency adjusting section 12 is driven via audio frequency adjusting software, and can be a treble boost section, a mid boost section, or a bass boost section. Via treble boost software, the treble boost section enhances the intensity of the signals of the first audio files 11 having a frequency of 2000 Hz. Via mid boost software, the mid boost section enhances the intensity of the signals of the first audio files 11 having a frequency of 1000 Hz. Via bass boost software, the bass boost section enhances the intensity of the signals of the first audio files 11 having a frequency of 100 Hz. When there is more than one first audio file 11 on the file-processing platform 1, the user may change the frequency property of the first audio files 11 via the audio frequency adjusting section 12 to create one or more second audio files (not shown) without the need of opening the first audio files on desktop.

FIG. 5 shows the method of processing audio files according to a fourth preferred embodiment of the present invention. As shown, the first audio files 11 and the audio frequency adjusting section 12 are provided on a file-processing platform 1. In addition, the first audio files 11 further correspond to a trial listening unit 13 and a stop unit 14 each. The audio frequency adjusting section 12 can be a treble boost section, a mid boost section, or a bass boost section. Via treble boost software, the treble boost section enhances the intensity of the signals of the first audio files 11 having a frequency of 2000 Hz. Via mid boost software, the mid boost section enhances the intensity of the signals of the first audio files 11 having a frequency of 1000 Hz. Via bass boost software, the bass boost section enhances the intensity of the signals of the first audio files 11 having a frequency of 100 Hz. When there is more than one first audio file 11 on the file-processing platform 1, the user may select a desired one of the first audio files 11 to be modified. And, the user may use the corresponding trial listening unit 13 and stop unit 14 to trial listen the selected first audio file 11 and decide whether to modify the selected file 11 or not. Then, the user may change the frequency property of the selected first audio file 11 via the audio frequency adjusting section 12 to create one or more second audio files (not shown) without the need of opening the selected first audio file 11 on desktop.

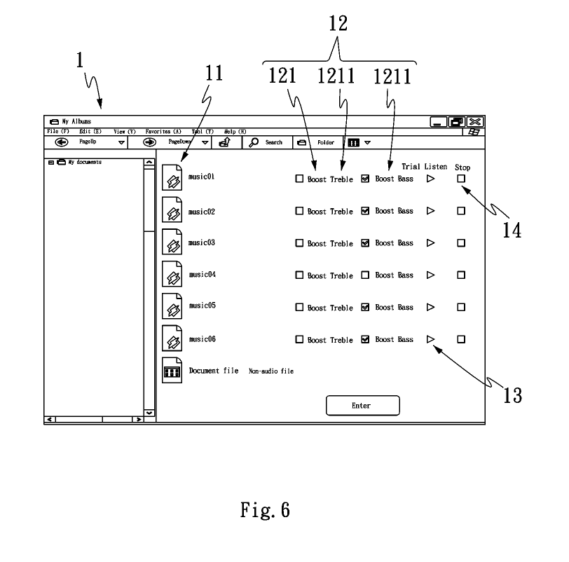

FIG. 6 shows the method of processing audio files according to a fifth preferred embodiment of the present invention. As shown, the first audio files 11 and the audio frequency adjusting section 12 may be provided on a file-processing platform 1, and the audio frequency adjusting section 12 includes one or more audio frequency adjusting modules 121 in one-to-one correspondence to the first audio files 11. Each of the audio frequency adjusting modules 121 includes one or more audio frequency adjusting units 1211. In addition, the first audio files 11 further correspond to a trial listening unit 13 and a stop unit 14 each. The audio frequency adjusting units 1211 can be a treble boost unit, a mid boost unit, or a bass boost unit. Via treble boost software, the treble boost units enhance the intensity of the signals of the first audio files 11 having a frequency of 2000 Hz. Via mid boost software, the mid boost units enhance the intensity of the signals of the first audio files 11 having a frequency of 1000 Hz. Via bass boost software, the bass boost units enhance the intensity of the signals of the first audio files 11 having a frequency of 100 Hz. When there is more than one first audio file 11 on the file-processing platform 1, the user may select one of the audio frequency adjusting units 1211 of the first audio file 11 to be modified. And, the user may use the corresponding trial listening unit 13 and stop unit 14 to trial listen the selected first audio file 11 and decide whether to modify the file 11 or not. Then, the user may change the frequency property of the selected first audio file 11 via the selected audio frequency adjusting unit 1211 to create a second audio file (not shown) without the need of opening the selected first audio file on desktop.

According to the above arrangements, the present invention provides a simplified measure for processing audio files, allowing a user without professional acoustic knowledge to quickly modify the frequency property that has most direct influences on the tone quality of the audio files, so that the time needed in optimizing the audio files is shortened.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A method of processing audio files, comprising the steps of:
(1) providing an audio frequency adjusting section; and
(2) changing a frequency property of one or more first audio files via the audio frequency adjusting section to create one or more second audio files without the need of opening the first audio files.

2. The method of processing audio files as claimed in claim 1, wherein the audio frequency adjusting section is driven via audio frequency adjusting software.

3. The method of processing audio files as claimed in claim 1, wherein the audio frequency adjusting section is selected from the group consisting of a treble boost section, amid boost section, and a bass boost section.

4. The method of processing audio files as claimed in claim 3, wherein the treble boost section enhances an intensity of signals of the first audio files having a frequency of 2000 Hz via treble boost software.

5. The method of processing audio files as claimed in claim 3, wherein the mid boost section enhances an intensity of signals of the first audio files having a frequency of 1000 Hz via mid boost software.

6. The method of processing audio files as claimed in claim 3, wherein the bass boost section enhances an intensity of signals of the first audio files having a frequency of 100 Hz via bass boost software.

7. The method of processing audio files as claimed in claim 1, wherein the first audio files and the audio frequency adjusting section are provided on a file-processing platform.

8. The method of processing audio files as claimed in claim 7, wherein the audio frequency adjusting section includes one or more audio frequency adjusting modules in one-to-one correspondence to the one or more first audio files, and wherein the each of the audio frequency adjusting modules includes one or more audio frequency adjusting units.

9. The method of processing audio files as claimed in claim 8, wherein the first audio files are in one-to-one correspondence to a trial listening unit and a stop unit each.

10. The method of processing audio files as claimed in claim 8, wherein the audio frequency adjusting units are driven via audio frequency adjusting software.

11. The method of processing audio files as claimed in claim 8, wherein the audio frequency adjusting units are selected from the group consisting of a treble boost unit, a mid boost unit, and a bass boost unit.

12. The method of processing audio files as claimed in claim 11, wherein the treble boost units enhance an intensity of signals of the first audio files having a frequency of 2000 Hz via treble boost software.

13. The method of processing audio files as claimed in claim 11, wherein the mid boost units enhance an intensity of signals of the first audio files having a frequency of 1000 Hz via mid boost software.

14. The method of processing audio files as claimed in claim 11, wherein the bass boost units enhance an intensity of signals of the first audio files having a frequency of 100 Hz via bass boost software.

15. The method of processing audio files as claimed in claim 7, wherein the audio frequency adjusting section is driven via audio frequency adjusting software.

16. The method of processing audio files as claimed in claim 7, wherein the audio frequency adjusting section is selected from the group consisting of a treble boost section, a mid boost section, and a bass boost section.

17. The method of processing audio files as claimed in claim 16, wherein the treble boost section enhances an intensity of signals of the first audio files having a frequency of 2000 Hz via treble boost software.

18. The method of processing audio files as claimed in claim 16, wherein the mid boost section enhances an intensity of signals of the first audio files having a frequency of 1000 Hz via mid boost software.

19. The method of processing audio files as claimed in claim 16, wherein the bass boost section enhances an intensity of signals of the first audio files having a frequency of 100 Hz via bass boost software.

20. The method of processing audio files as claimed in claim 16, wherein the first audio files are in a one-to-one correspondence to a trial listening unit and a stop unit each.
